(19) United States
(12) Patent Application Publication
(10) Pub. No.: US 2024/0224703 A1
(43) Pub. Date: Jul. 4, 2024

(54) Display Device and Method for Manufacturing the Same

(71) Applicant: LG Display Co., Ltd., Seoul (KR)

(72) Inventor: Hyunsu Lee, Goyang-si (KR)

(21) Appl. No.: 18/469,262

(22) Filed: Sep. 18, 2023

(30) Foreign Application Priority Data
Dec. 30, 2022 (KR) 10-2022-0191252

(51) Int. Cl. H10K 59/65; H10K 59/121; H10K 59/123; H10K 59/80

(52) U.S. Cl. CPC H10K 59/65; H10K 59/1213; H10K 59/123; H10K 59/8792

(57) ABSTRACT

Disclosed are a display device and a method for manufacturing the same, in which black ink of a conductive material is not disposed and a light-shielding tape is disposed and attached to a through-hole of a camera area formed to receive therein a camera of a hole in display. A plate is disposed under a panel in which a camera area including a first hole area is formed in a display area, and the through-hole are formed in each of the panel and the plate in the camera area, and the light-shielding tape extends along and is attached to an inner side surface of the through-hole. Therefore, the light-shielding tape is attached to the through-hole of the camera area by a double pressing technique, thereby preventing light-leakage and reducing a bright spot defect.

### CROSS-REFERENCE TO RELATED APPLICATION

This application claims priority from Republic of Korea Patent Application No. 10-2022-0191252 filed on Dec. 30, 2022 in the Korean Intellectual Property Office, which is hereby incorporated by reference in its entirety.

### TECHNICAL FIELD

The present disclosure relates to a display device and method for manufacturing the same.

### BACKGROUND

Recent display devices capable of displaying various information and interacting with users who view the information are required to have various sizes, various shapes, and various functions.

These display devices include a liquid crystal display device (LCD), an electrophoretic display device (EPD), an inorganic light-emitting display device, and an organic light-emitting display device (OLED).

The organic light-emitting display device is a self-luminous display device, and does not require a separate light source, and thus can be manufactured in a lightweight and thin form. Moreover, the organic light-emitting display device is not only advantageous in terms of power consumption due to low voltage operation, but also is excellent in terms of color rendering, response speed, viewing angle, and contrast ratio (CR), and thus is being studied as a next-generation display.

### SUMMARY

The display device is being developed so as to have a camera, a speaker, and a sensor added thereto.

In order to place a camera, sensor, etc. on a display device, a hole in display structure is applied in which a hole is defined in a panel of the display device.

When the hole is defined in the panel of the display device, a light-leakage phenomenon occurs in which light in a display area leaks through the hole.

Moreover, when the user touches the display device, charges generated by friction on a cover member do not escape to a metal plate but flow into the panel to damage the panel, resulting in a bright spot defect.

Accordingly, in order to solve the above-mentioned problems, the inventor of the present disclosure has invented a display device that lacks black ink of a conductive material but instead uses a light-shielding tape for shielding the light-leakage in a through-hole of a camera area formed to place a camera of the hole in display, thereby preventing the light-leakage and removing the bright spot defect.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

A display device according to an embodiment of the present disclosure may be provided. The display device includes a panel including a display area and a non-display area, wherein a camera area including a first hole area is formed in the display area; a cover member disposed under the panel; and a plate disposed on the panel, wherein each of the panel and the plate has a through-hole defined therein in the camera area, wherein a light-shielding tape is disposed along and attached to an inner side surface of the through-hole of each of the panel and the plate.

Moreover, a method for manufacturing a display device according to an embodiment of the present disclosure may be provided, wherein the display device includes: a panel including a display area and a non-display area, wherein a camera area including a first hole area is formed in the display area; a cover member disposed on the panel; and a plate disposed under the panel and including a support member and a metal plate, wherein each of the panel and the plate has a through-hole defined therein in the camera area, wherein the method comprises: positioning a light-shielding tape on the through-hole and the metal plate; first pressing a body of the light-shielding tape using a first pressure pusher having a smaller diameter than a diameter of the through-hole; second pressing legs of the light-shielding tape using a second pressure pusher having a larger diameter than the diameter of the through-hole; and removing the first and second pressure pushers from the light-shielding tape.

Details of other embodiments are included in the detailed description and drawings.

The technical solutions according to the embodiment of the present disclosure are not limited to the solutions mentioned above, and other solutions not mentioned will be clearly understood by those skilled in the art from the description below.

In the display device according to the embodiment of the present disclosure, the light-shielding tape may be attached to the through-hole of the camera area in the double pressing technique, thereby preventing the light-leakage and reducing the bright spot defect.

Moreover, the manufacturing method of the display device according to the embodiment of the present disclosure can manufacture the display device in an easier manner than the manufacturing method of the display device including a process of applying black ink to the through-hole of the camera area. Thus, the defect may be reduced by securing reproducibility. This may optimize the process.

Moreover, the manufacturing method of the display device according to the embodiment of the present disclosure may have a reduced material cost than the manufacturing method of the display device including a process of applying black ink to the through-hole of the camera area. As a result, a manufacturing cost may be reduced.

Moreover, in the display device according to the embodiment of the present disclosure, the light-shielding tape may be placed in the camera area formed to receive therein the camera in the display area. Thus, the light-leakage and static electricity caused by user's touch may be prevented.

Therefore, the display device according to the embodiment of the present disclosure may prevent the light-leakage, the static electricity and the bright spot generated in the camera area of the panel. Thus, the damage to the display panel may be prevented.

In addition to the above effects, specific effects of the present disclosure are described together while describing specific details for carrying out the present disclosure.

Effects of the present disclosure are not limited to the effects mentioned above, and other effects not mentioned will be clearly understood by those skilled in the art from the descriptions below.

### BRIEF DESCRIPTION OF THE DRAWINGS

FIG. 1 is a plan view illustrating a display device according to an embodiment of the present disclosure.

FIG. 2 is an enlarged view showing a camera area CA of FIG. 1 according to an embodiment of the present disclosure.

FIG. 3 is a cross-sectional view of a panel as cut along a cutting line 3-3′ of FIG. 1 according to an embodiment of the present disclosure.

FIG. 4 is a cross-sectional view of a panel as cut along a cutting line 4-4′ of FIG. 1 according to an embodiment of the present disclosure.

FIG. 5 is a cross-sectional view of a display device as cut along a cutting line 4-4′ of FIG. 2 according to an embodiment of the present disclosure.

FIG. 6 is a diagram schematically showing a structure of a light-shielding tape according to an embodiment of the present disclosure.

FIG. 7 is a flowchart illustrating a method for manufacturing a display device according to an embodiment of the present disclosure.

FIG. 8 is a view showing an example in which the light-shielding tape according to the embodiment of the present disclosure is first pressure-bonded and is second pressure-bonded.

FIGS. 9A and 9B are diagrams showing a light-leakage phenomenon before and after the light-shielding tape is attached to a through-hole of a camera area of a display device according to an embodiment of the present disclosure.

### DETAILED DESCRIPTION

Advantages and features of the present disclosure, and a method of achieving the advantages and features will become apparent with reference to embodiments described later in detail together with the accompanying drawings. However, the present disclosure is not limited to the embodiments as disclosed under, but may be implemented in various different forms. Thus, these embodiments are set forth only to make the present disclosure complete, and to completely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for describing embodiments of the present disclosure are illustrative, and the present disclosure is not limited thereto. The same reference numerals refer to the same elements herein. Further, descriptions and details of well-known steps and elements are omitted for simplicity of the description.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “including”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described under could be termed a second element, component, region, layer or section, without departing from the spirit and scope of the present disclosure.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects,” and the like should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for describing embodiments.

Further, in a specific case, a term may be arbitrarily selected by the applicant, and in this case, the detailed meaning thereof will be described in a corresponding description section. Therefore, the terms used in the description below should be understood based on not simply the name of the terms, but the meaning of the terms and the contents throughout the Detailed Descriptions.

In description of flow of a signal, for example, when a signal is delivered from a node A to a node B, this may include a case where the signal is transferred from the node A to the node B via another node unless a phrase ‘immediately transferred’ or ‘directly transferred’ is used.

As used herein, the term “display device” may include, in a narrow sense, a display device including a liquid crystal module (LCM), an organic light-emitting diode (OLED) module, or a quantum dot (QD) module including a display panel and a driver for driving the display panel. Moreover, the display device may include, in a broad sense, a laptop computer, a television, a computer monitor, an automotive device or an equipment display for a vehicle, a set electronic device, a set device or a set apparatus including a complete product or a final product including the LCM, the OLED module, or the QD module.

Therefore, the display device in accordance with the present disclosure may include, in the narrow sense, a display device itself including, for example, the LCM, the OLED module, QD module, etc., and may include, in a broad sense, the set device as an application product or an end-user device including a complete product or a final product including the LCM, the OLED module, or the QD module.

Moreover, in some cases, the LCM, OLED module, or QD module composed of the display panel and the driver may be expressed as “display device” in a narrow sense. The electronic device as a complete product including the LCM, OLED module or QD module may be expressed as “set device” in a broad sense. For example, the display device in the narrow sense may include a display panel such as a liquid crystal panel, an organic light-emitting display panel, or a quantum dot display panel, and a source PCB as a controller for driving the display panel. The set device in the broad sense may include a display panel such as a liquid crystal panel, an organic light-emitting display panel, or a quantum dot display panel, a source PCB as a controller for driving the display panel, and a set PCB as a set controller that is electrically connected to the source PCB and controls the set device.

As used herein, the display panel may be of any type of the display panels such as a liquid crystal display panel, an organic light emitting diode (OLED) display panel, a quantum dot (QD) display panel, and an electroluminescent display panel, etc. Embodiments are not limited thereto. For example, the display panel may be embodied as a display panel which may be vibrated by a vibrating device according to an embodiment of the present disclosure to generate a sound. A display panel applied to a display device according to an embodiment of the present disclosure is not limited to a shape or a size of the display panel.

Hereinafter, various embodiments of the present disclosure will be described in detail with reference to drawings.

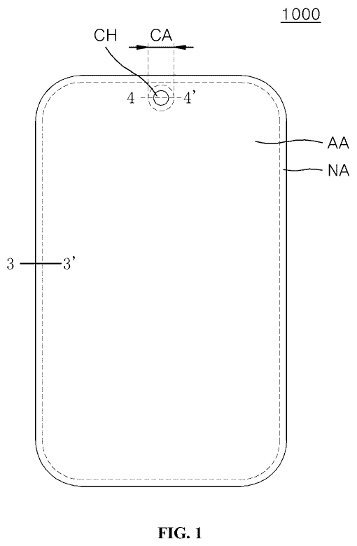

FIG. 1 is a plan view schematically illustrating an example of a display device according to an embodiment of the present disclosure.

A display device 1000 may include a plurality of areas. For example, the display device 1000 may include one or more display areas AA where an image is displayed, and pixels may be formed in the display area AA. One or more non-display areas NA in which an image is not displayed may include a driving circuit and a dam area, and may be disposed on one side of the display area AA. For example, the non-display area NA may be adjacent to one or more sides of the display area AA.

Referring to FIG. 1, the non-display area NA may surround the display area AA. It should be understood that a shape of the display area AA and a position of the non-display area NA adjacent to the display area AA are not specifically limited to those in the display device 1000 as shown in FIG. 1. Each of the display area AA and the non-display area NA may have any shape. Examples of these shapes may include a pentagon, a hexagon, a circle, an oval, etc. An embodiment of the present disclosure is not limited thereto.

In the display area AA, a plurality of pixels are disposed. Each pixel includes sub-pixels, and each sub-pixel includes a pixel circuit.

The sub-pixel may display a color such as red (R), green (G), blue (B), or white (W). Moreover, each pixel or sub-pixel may be associated with a pixel circuit, including one or more thin film transistors (TFTs) which are disposed on a substrate of the display device 1000. Each pixel circuit may be electrically connected to a gate line and a data line to communicate with one or more driving circuits, for example, a gate driver and a data driver located in the non-display area NA of the display device 1000.

One or more driving circuits may be implemented as TFTs disposed in the non-display area NA as shown in FIG. 1. For example, the gate driver may be implemented using a plurality of TFTs on the substrate of the panel. Non-limiting examples of circuits that may be implemented as the TFTs of the substrate include an inverter circuit, a multiplexer, and an ESD (electro static discharge) circuit. An embodiment of the present disclosure is not limited thereto.

Some driving circuits may be provided as IC (integrated circuit) chips, and may be mounted in the non-display area NA of the display device 1000 using a COG (chip-on-glass) or in other similar schemes. Moreover, some driving circuits may be mounted on another substrate, and may be coupled to a connection interface (pads/bumps, pins) disposed in the non-display area NA using a printed circuit board such as a flexible PCB (flexible printed circuit board: FPCB), COF (chip-on-film), TCP (tape-carrier-package) or other suitable schemes.

In embodiments of the present disclosure, at least two different types of TFTs are disposed in a TFT substrate for a display device. The types of TFTs employed in a portion of the pixel circuit and a portion of the driving circuit may vary according to the requirements of the display device.

For example, the pixel circuit may be implemented as a TFT (oxide TFT) with an oxide active layer. The driving circuit may be implemented as a TFT (LTPS TFT) with a low-temperature polycrystalline silicon active layer and a TFT with an oxide active layer. Unlike the LTPS TFTs, the oxide TFTs do not suffer from pixel-to-pixel threshold voltage Vth variation. A uniform threshold voltage Vth may also be obtained in an array of pixel circuits for display. The uniformity problem of the threshold voltages Vth of the TFTs implementing the driving circuit will have less direct impact on the luminance uniformity of the pixels.

Driving circuits, for example, a gate driver may have the gate driver IC embedded inside the display panel to reduce the number of driver ICs to achieve cost reduction, and may provide a high-speed scan signal to the display area of the display panel.

Using the driving circuits on the substrate to be implemented as the LTPS TFTs, signals and data may be provided to pixels at a higher clock than that when all TFTs in the TFT panel are embodied as oxide TFTs. Therefore, the display device capable of high-speed operation may be realized without stains such as mura. For example, the advantages of the oxide TFT and the LTPS TFT are combined with the design of the TFT panel such that the oxide TFT and the LTPS TFT may be selectively used according to the advantage thereof.

In the present disclosure, a panel may include a plurality of metal layers and insulating layers constituting the display circuit for driving the display device from the substrate.

The display device 1000 of the present disclosure includes an optical control layer and cover member disposed on the panel and a support member and a metal plate disposed under the panel. The panel and the optical control layer may be bonded to each other by a first adhesive layer. The optical control layer and the cover member may be bonded to each other by a cover adhesive layer. The panel and the support member may be bonded to each other by a second adhesive layer. The support member and the metal plate may be bonded to each other by a third adhesive layer.

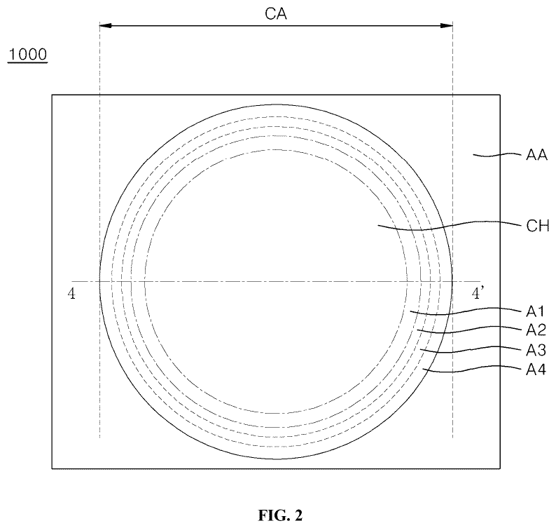

FIG. 2 is an enlarged view showing a camera area CA of FIG. 1 according to one embodiment.

Referring to FIG. 2, the display area AA of the display device 1000 may include the camera area CA. In order to place a camera in the display area AA, the camera area CA includes a camera hole area CH, and a first area A1, a second area A2, a third area A3, and a fourth area A4 surrounding the camera hole area CH. These components are described in detail later. Each of the first area A1, the second area A2, the third area A3, and the fourth area A4 may have a circular ring shape.

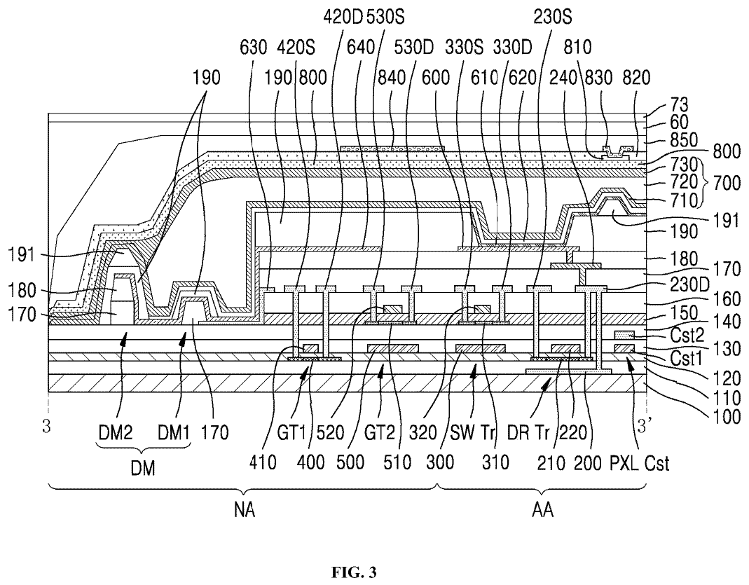

FIG. 3 is a cross-sectional view of a panel cut along a cutting line 3-3′ of FIG. 1 according to an embodiment of the present disclosure.

Referring to FIG. 3, the substrate 100 of the display device according to an embodiment of the present disclosure may include a first substrate and a second substrate, and an intermediate layer between the first substrate and the second substrate.

Each of the first substrate and the second substrate may be made of at least one of polyimide, polyethersulfone, polyethylene terephthalate, and polycarbonate. Embodiments of the present disclosure are not limited thereto.

When the substrate is made of plastic material, a display device manufacturing process is performed while a support substrate made of glass is disposed under the substrate. After the manufacturing process of the display device is completed, the support substrate may be released therefrom.

Moreover, after the support substrate has been released, a support member (back plate) for supporting the substrate may be disposed below the substrate. When the substrate is made of plastic material, moisture permeates the substrate and invade the thin-film transistor or the light-emitting element layer, which may deteriorate the performance of the display device.

The display device according to the embodiment of the present disclosure may include two substrates, that is, a first substrate and a second substrate made of a plastic material, in order to prevent performance degradation of the display device due to moisture permeation.

Further, an inorganic film as an intermediate layer may be disposed between the first substrate and the second substrate, preventing moisture from penetrating the substrate to improve the performance reliability of the product.

The intermediate layer may be embodied as an inorganic film. For example, the intermediate layer may be composed of a single layer or multiple layers made of silicon nitride (SiNx) or silicon oxide (SiOx). However, the present disclosure is not limited thereto.

The display device may include a plurality of areas. In the present disclosure, the plurality of areas may include the display area AA and the non-display area NA. However, the present disclosure is not limited thereto.

A buffer layer composed of a single layer or a multilayer made of silicon nitride (SiNx) or silicon oxide (SiOx) may be disposed on one surface of the substrate 100 and in the display area AA and the non-display area NA.

The buffer layer may improve the adhesion between the layers formed on the buffer layer and the substrate 100 and block various types of defect factors such as alkali components flowing out of the substrate 100.

Moreover, the buffer layer may delay the diffusion of moisture or oxygen that has penetrated into the substrate 100. The buffer layer may be omitted based on the type and material of the substrate, the structure and type of the thin-film transistor, and the like.

The thin-film transistors may be formed on the substrate 100 and the buffer layer and in the display area AA and the non-display area NA. The thin-film transistors of the display area AA may include a switching transistor SW Tr and a driving transistor DR Tr for operating a sub-pixel.

In addition, a pixel capacitor PXL Cst may be formed in the display area AA. The thin-film transistors of the non-display area NA may include a first gate driving transistor GT1 and a second gate driving transistor GT2 for driving the gate driver.

The driving transistor DR Tr of the display area AA may include a light-blocking layer 200 disposed on the substrate 100 or the buffer layer.

The light-blocking layer 200 may prevent or at least reduce the light from being directed to the first semiconductor layer 210 of the driving transistor DR Tr, and may be connected to a first drain electrode 230D so as to prevent or at least reduce a phenomenon in which parasitic carriers are accumulated in the first semiconductor layer 210 such that a drain current rapidly increases, or change in the threshold voltage due to this phenomenon.

The light-blocking layer 200 may be composed of a single layer or multiple layers made of at least one of titanium (Ti), molybdenum (Mo), copper (Cu), aluminum (Al), silver (Ag), chromium (Cr), gold (Au), neodymium (Nd), and nickel (Ni). Embodiments of the present disclosure are not limited thereto.

A first insulating layer 110 may be disposed on the light-blocking layer 200.

The first insulating layer 110 may be made of an insulating material such as silicon nitride (SiNx) or silicon oxide (SiOx). Alternatively, the first insulating layer 110 may be made of an insulating inorganic or organic material. Embodiments of the present disclosure are not limited thereto.

A first semiconductor layer 210 of the driving transistor DR Tr of the display area AA and a second semiconductor layer 400 of the first gate driving transistor GT1 of the non-display area NA may be disposed on the first insulating layer 110. The first semiconductor layer 210 may overlap the light-blocking layer 200.

Each of the first semiconductor layer 210 and the second semiconductor layer 400 may be made of Low Temperature Polycrystalline Silicon (LTPS). Embodiments of the present disclosure are not limited thereto.

The semiconductor layer may include a channel area where a channel through which electrons or holes migrate is formed, a source area, and a drain area.

Conductive characteristics of the source area and the drain area may be improved by, for example, a doping process in which impurities are implanted. During the etching process for forming the gate electrode on the metal oxide semiconductor, oxygen in the metal oxide semiconductor area that does not overlap with the gate electrode is released, and thus the conductivity increases, the area may become conductive. Thus, a source electrode and a drain electrode may be connected to the source area and the drain area, respectively.

A first gate insulating layer 120 may be disposed on the first semiconductor layer 210 and the second semiconductor layer 400. The first gate insulating layer 120 may be made of an insulating material such as silicon nitride (SiNx) or silicon oxide (SiOx) or may be made of an insulating inorganic or organic material. Embodiments of the present disclosure are not limited thereto.

A first gate electrode 220 and a second gate electrode 410 may be disposed on the first gate insulating layer 120 so as to overlap the first semiconductor layer 210 and the second semiconductor layer 400, respectively. Each of the first gate electrode 220 and the second gate electrode 410 may include one or more of silver (Ag), molybdenum (Mo), copper (Cu), titanium (Ti), aluminum (Al), chromium (Cr), nickel (Ni), neodymium (Nd), tungsten (W), and gold (Au). Embodiments of the present disclosure are not limited thereto.

A first capacitor electrode Cst1 of a pixel capacitor PXL Cst included in the sub-pixel, a first metal layer 300 overlapping with a switching transistor SW Tr of the sub-pixel, and a second metal layer 500 overlapping with the second gate driving transistor GT2 may be disposed on the first gate insulating layer 120. The first gate electrode 220 and the second gate electrode 410 may be formed through the same process.

The first metal layer 300 and the second metal layer 500 may act as lower gate electrodes of the switching transistor SW Tr and the second gate driving transistor GT2, respectively. Alternatively, the first metal layer 300 and the second metal layer 500 may be used as light blocking layers to block light to be reflected to a third semiconductor layer 310 and a fourth semiconductor layer 510 of the switching transistor SW Tr and the second gate driving transistor GT2, respectively. Embodiments of the present disclosure are not limited thereto.

A second insulating layer 130 may be disposed on the first gate electrode 220, the second gate electrode 410, the first metal layer 300, the second metal layer 500, and the first capacitor electrode Cst1.

The second insulating layer 130 may be made of an insulating material such as silicon nitride (SiNx) or silicon oxide (SiOx) or may be made of an insulating inorganic or organic material. Embodiments of the present disclosure are not limited thereto.

A second capacitor electrode Cst2 of the pixel capacitor PXL Cst may be disposed on the second insulating layer 130. The second capacitor electrode Cst2 may overlap with the first capacitor electrode Cst1, and may be made of the same material as that of the first capacitor electrode Cst1.

A third insulating layer 140 may be disposed on the second capacitor electrode Cst2.

The third insulating layer 140 may be made of an insulating material such as silicon nitride (SiNx) or silicon oxide (SiOx) or may be made of an insulating organic material, etc. Embodiments of the present disclosure are not limited thereto.

The third semiconductor layer 310 of the switching transistor SW Tr of the display area AA and the fourth semiconductor layer 510 of the second gate driving transistor GT2 of the non-display area NA may be disposed on the third insulating layer 140.

Each of the third semiconductor layer 310 and the fourth semiconductor layer 510 may be embodied as a metal oxide semiconductor, for example, one of IGZO (Indium-gallium-zinc-oxide), IZO (Indium-zinc-oxide), IGTO (Indium-gallium-tin-oxide), and IGO (Indium-gallium-oxide). Embodiments of the present disclosure are not limited thereto.

A second gate insulating layer 150 may be disposed on the third semiconductor layer 310 and the fourth semiconductor layer 510. A third gate electrode 320 and a fourth gate electrode 520 may be disposed on the second gate insulating layer 150. The second gate insulating layer 150 may be disposed between the third semiconductor layer 310 and the fourth semiconductor layer 510 and the third gate electrode 320 and the fourth gate electrode 520 so as to electrically insulate the third semiconductor layer 310 and the fourth semiconductor layer 510 from the third gate electrode 320 and the fourth gate electrode 520.

A source area and a drain area connected to a channel area and respectively connected to a source electrode and a drain electrode may be formed in each of the third semiconductor layer 310 and the fourth semiconductor layer 510 through a doping process.

The second gate insulating layer 150 may be made of an insulating inorganic material such as silicon nitride (SiNx) or silicon oxide (SiOx) or may be made of an insulating organic material, etc. However, the present disclosure is not limited thereto.

The third gate electrode 320 and the fourth gate electrode 520 may be disposed to overlap the third semiconductor layer 310 and the fourth semiconductor layer 510, respectively.

Each of the third gate electrode 320 and the fourth gate electrode 520 may be composed of a single layer or multi-layers made of one of silver (Ag), molybdenum (Mo), copper (Cu), titanium (Ti), aluminum (Al), chromium (Cr), nickel (Ni), neodymium (Nd), tungsten (W), and gold (Au) or an alloy thereof. Embodiments of the present disclosure are not limited thereto.

A fourth insulating layer 160 may be disposed on the third gate electrode 320 and the fourth gate electrode 520.

The fourth insulating layer 160 may be made of an insulating inorganic material such as silicon nitride (SiNx) or silicon oxide (SiOx), or an organic insulating material such as BCB (BenzoCycloButene), acryl resin, epoxy resin, phenolic resin, polyamide resin, or polyimide resin. Embodiments of the present disclosure are not limited thereto.

A first source electrode 230S and a first drain electrode 230D connected to the first semiconductor layer 210, a second source electrode 420S and a second drain electrode 420D connected to the second semiconductor layer 400, a third source electrode 330S and a third drain electrode 330D connected to the third semiconductor layer 310, and a fourth source electrode 530S and a fourth drain electrode 530D connected to the fourth semiconductor layer 510 may be disposed on the fourth insulating layer 160.

The first source electrode 230S, the first drain electrode 230D, the second source electrode 420S and the second drain electrode 420D may be connected to the first semiconductor layer 210 and the second semiconductor layer 400 via contact-holes formed in the first gate insulating layer 120, the second insulating layer 130, the third insulating layer 140, the second gate insulating layer 150 and the fourth insulating layer 160.

The third source electrode 330S, the third drain electrode 330D, the fourth source electrode 530S, and the fourth drain electrode 530D may be connected to the third semiconductor layer 310 and the fourth semiconductor layer 510 via contact-holes formed in the second gate insulating layer 150 and the fourth insulating layer 160.

The first source electrode 230S, the first drain electrode 230D, the second source electrode 420S, the second drain electrode 420D, the third source electrode 330S, the third drain electrode 330D, the fourth source electrode 530S and the fourth drain electrode 530D may be formed in the same process. Each of the first source electrode 230S, the first drain electrode 230D, the second source electrode 420S, the second drain electrode 420D, the third source electrode 330S, the third drain electrode 330D, the fourth source electrode 530S and the fourth drain electrode 530D may be made of one or more of silver (Ag), molybdenum (Mo), copper (Cu), titanium (Ti), aluminum (Al), chromium (Cr), nickel (Ni), neodymium (Nd), tungsten (W), and gold (Au). Embodiments of the present disclosure are not limited thereto.

A first line 630 may be disposed in the non-display area NA. The first line 630, the first source electrode 230S, the first drain electrode 230D, the second source electrode 420S, the second drain electrode 420D, the third source electrode 330S, the third drain electrode 330D, the fourth source electrode 530S and the fourth drain electrode 530D may be formed in the same process.

The first line 630 may be a line for transmitting a voltage to the second electrode 620.

A first planarization layer 170 may be disposed on the first source electrode 230S, the first drain electrode 230D, the second source electrode 420S, the second drain electrode 420D, the third source electrode 330S, the third drain electrode 330D, the fourth source electrode 530S, and the fourth drain electrode 530D.

The first planarization layer 170 may be embodied as an organic insulating layer made of polyacrylate and polyimide, and may planarize a step caused by underlying lines and contact-holes.

A connection electrode 240 for connecting the first drain electrode 230D and a first electrode 600 to each other may be disposed on the first planarization layer 170.

The connection electrode 240 may be electrically connected to the first drain electrode 230D via a contact-hole formed in the first planarization layer 170.

The connection electrode 240 may include at least one of titanium (Ti), molybdenum (Mo), copper (Cu), aluminum (Al), silver (Ag), chromium (Cr), gold (Au), neodymium (Nd), nickel (Ni), or an alloy thereof. Embodiments of the present disclosure are not limited thereto.

A second planarization layer 180 may be disposed on the connection electrode 240. The second planarization layer 180 may be composed of an organic insulating layer made of polyacrylate and polyimide. Embodiments of the present disclosure are not limited thereto.

The first electrode 600 may be disposed on the second planarization layer 180. The first electrode 600 may be electrically connected to the connection electrode 240 via a through-hole formed in the second planarization layer 180. The first electrode 600 may be an anode electrode.

A second line 640 may be formed in the non-display area NA in the same process as a process of forming the first electrode 600. The second line 640 may overlap a portion of each of the first gate driving transistor GT1 and the second gate driving transistor GT2. The second line 640 may be connected to the first line 630 disposed in the non-display area NA so as to apply the voltage to the second electrode 620. The second electrode 620 may be a cathode electrode.

Each of the first electrode 600 and the second line 640 may be made of at least one or more of silver (Ag), aluminum (Al), gold (Au), molybdenum (Mo), tungsten (W), chromium (Cr), lead (Pd), indium tin oxide (ITO), indium zinc oxide (IZO), or alloys thereof. Embodiments of the present disclosure are not limited thereto.

A bank 190 may be disposed on the first electrode 600, the second line 640, and the second planarization layer 180.

The bank 190 may define each of a plurality of sub-pixels, and may minimize light blurring and prevent color mixing occurring in various viewing angles.

The bank 190 may not cover a portion of the first electrode 600 corresponding to the light-emitting area and may overlap an end of the first electrode 600.

The bank 190 may be made of at least one or more materials of an inorganic insulating material such as silicon nitride (SiNx) or silicon oxide (SiOx) or an organic insulating material such as BCB (BenzoCycloButene), acryl resin, epoxy resin, phenolic resin, polyamide resin, or polyimide resin. However, the present disclosure is not limited thereto.

A spacer 191 may be further disposed on the bank 190. The spacer 191 protrudes on the bank 190 and supports a fine metal mask (FMM) when depositing the organic light-emissive layer in the light-emitting area. The spacer 191 supports the fine metal mask such that the bank 190 may be prevented from being damaged by the fine metal mask. The spacer 191 may be made of the same material as that of the bank 190, and may be formed at the same time as the formation of the bank 190. However, the present disclosure is not limited thereto.

A light-emitting element layer 610 may be disposed on an opening defined in the bank 190 exposing the first electrode 600. The light-emitting element layer 610 includes at least one organic light-emissive layer among a red light-emissive layer, a green light-emissive layer, a blue light-emissive layer, and a white light-emissive layer in order to emit light of a specific color. Moreover, the light-emitting element layer 610 may further include a hole injection layer, a hole transport layer, an electron transport layer, and an electron injection layer in addition to the organic light-emissive layer. However, the present disclosure is not limited thereto.

A thickness and a material of each of the hole injection layer, the hole transport layer, the electron transport layer, and the electron injection layer may vary on a sub-pixel basis. Alternatively, each of the hole injection layer, the hole transport layer, the electron transport layer, and the electron injection layer may be commonly disposed across an entirety of the display area.

When the light-emitting element layer 610 includes a white organic light-emissive layer, the light-emitting element layer 610 may be disposed across the opening of the bank 190 and an entirety of the substrate.

A color filter may be disposed on the light-emitting element layer 610 so as to convert the white light emitted from the white organic light-emissive layer into light of a different color.

A second electrode 620 may be disposed on the light-emitting element layer 610. The second electrode 620 supplies electrons to the light-emitting element layer 610 and may be made of a conductive material having a low work function.

When the display device 1000 operates in a top-emission scheme, the second electrode 620 may be made of a transparent conductive material through which light transmits. For example, the transparent conductive material may include at least one or more of indium tin oxide (ITO), and indium zinc oxide (IZO). However, the present disclosure is not limited thereto.

Moreover, the second electrode 620 may be made of a transflective conductive material through which light transmits. For example, the second electrode 620 may be made of at least one or more of alloys such as LiF/Al, CsF/Al, Mg:Ag, Ca/Ag, Ca:Ag, LiF/Mg:Ag, LiF/Ca/Ag, and LiF/Ca:Ag. However, the present disclosure is not limited thereto.

When the display device 1000 operates in a bottom-emission scheme, the second electrode 620 may act as a reflective electrode that reflects light and may be made of an opaque conductive material. For example, the second electrode 620 may be made of at least one of silver (Ag), aluminum (Al), gold (Au), molybdenum (Mo), tungsten (W), chromium (Cr), or an alloy thereof.

The non-display area NA of the display device 1000 has an end in which a second dam area in which a plurality of dams are disposed and the driving circuit are disposed.

In the end of the non-display area NA, a connection portion electrically connected to the second electrode 620 and lines for applying voltage to the second electrode 620, and the second dam area DM may be disposed. The second dam area DM in which the plurality of dams are disposed may be an area where the display device 1000 is sealed.

The first insulating layer 110, the first gate insulating layer 120, the second insulating layer 130, and the third insulating layer 140 disposed on the substrate 100 may extend into the end of the non-display area NA.

The lines may be disposed in the end of the non-display area NA so that touch signals and a power voltage applied from the FPCB of the display device 1000 are applied to the display panel via the lines.

The first line 630 may be disposed on a portion of a top surface of the fourth insulating layer 160, may contact side surfaces of the fourth insulating layer 160 and the second gate insulating layer 150, and may extend between a first dam DM1 of the non-display area NA and the third insulating layer 140.

The first dam DM1 may be formed using the same materials and the same processes as those of the first planarization layer 170 and the bank 190.

A second dam DM2 may be formed using the same materials and the same processes as those of the first planarization layer 170, the second planarization layer 180, the bank 190 and the spacer 191.

The first dam DAM1 and the second dam DAM2 may have a first height and a second height, respectively, and may surround the display area AA.

The second height of the second dam DAM2 may be larger than the first height of the first dam DAM1. Even when a second encapsulating layer 720 of an encapsulating layer 700 as described later extends over the first dam DM1 of the second dam area DM, the second encapsulating layer 720 may not extend over the second dam DM2 and may be blocked with the second dam DM2 and thus may not be disposed outside the second dam area DM.

The first encapsulating layer 710 and a third encapsulating layer 730 of the encapsulating layer 700 may be disposed to extend beyond the second dam DM2 to an outside out of the second dam area DM.

The second line 640 may extend between the first planarization layer 170 and the bank 190 of the first dam DM1 and between the second planarization layer 180 and the bank 190 of the second dam DM2.

The second electrode 620 may extend to an area between the first dam DM1 and the second dam DM2 so as to be electrically connected to the first line 630 and the second line 640.

The encapsulating layer 700 may be disposed on the second electrode 620 of the display area AA, and the second electrode 620 and the second dam DM2 of the non-display area NA.

The encapsulating layer 700 may protect the display device 1000 from external moisture, oxygen, or foreign matter. For example, the encapsulating layer 700 may prevent penetration of oxygen and moisture from the outside into the light-emitting material and the electrode material in order to prevent oxidation of the light-emitting material and the electrode material.

The encapsulating layer 700 may be made of a transparent material so that light emitted from the light-emitting element layer 610 transmits therethrough.

The encapsulating layer 700 may include the first encapsulating layer 710, the second encapsulating layer 720, and the third encapsulating layer 730 that block penetration of moisture or oxygen. Embodiments of the present disclosure are not limited thereto. The encapsulating layer 700 may have a stack structure in which the first encapsulating layer 710, the second encapsulating layer 720, and the third encapsulating layer 730 are sequentially stacked. Embodiments of the present disclosure are not limited thereto.

Each of the first encapsulating layer 710 and the third encapsulating layer 730 may be made of at least one inorganic material selected from silicon nitride (SiNx), silicon oxide (SiOx), and aluminum oxide (AlyOz). However, the present disclosure is not limited thereto.

The second encapsulating layer 720 may block foreign substances or particles that may occur in the manufacturing process. Moreover, the second encapsulating layer 720 may planarize a surface step of the first encapsulating layer 710.

The second encapsulating layer 720 may be made of an organic material, for example, a polymer such as silicon oxycarbide (SiOC), epoxy, polyimide, polyethylene, acrylate, etc. However, the present disclosure is not limited thereto.

A touch buffer layer 800 may be disposed on the third encapsulating layer 730. The touch buffer layer 800 may be disposed on an entirety of the display area AA and the non-display area NA, and may extend to and be disposed on a pad area.

The touch buffer layer 800 may be made of at least one inorganic material selected from silicon nitride (SiNx), silicon oxide (SiOx), and aluminum oxide (AlyOz). However, the present disclosure is not limited thereto.

A first touch electrode 810 may be disposed on the touch buffer layer 800.

A touch operation may be achieved by a plurality of sensing electrodes and a plurality of driving electrodes disposed in the display area AA. The sensing electrode includes a plurality of sub-sensing electrodes which extend along the first direction and are arranged to be spaced from each other by a certain spacing along the second direction. A plurality of sensing electrodes may not be disconnected but be continuous in the first direction. The first direction and the second direction may intersect each other. For example, the first direction and the second direction may be orthogonal to each other.

Each of the plurality of driving electrodes includes a plurality of sub-driving electrodes which extend along the second direction and are arranged to be spaced from each other by a certain spacing along the first direction. The plurality of sub-driving electrodes may be electrically connected to each other in the second direction.

When the plurality of sub-sensing electrodes and the plurality of sub-driving electrodes are formed in the same layer, the plurality of sub-driving electrodes may be electrically connected to each other via a bridge pattern.

The plurality of sub-sensing electrodes and the plurality of sub-driving electrodes may have a metal mesh structure.

Moreover, the plurality of sub-sensing electrodes may be electrically connected to each other via the bridge pattern, while the plurality of sub-driving electrodes may be continuous and be electrically connected to each other.

The first touch electrode 810 may be the plurality of sub-sensing electrodes or the plurality of sub-driving electrodes.

The first touch electrode 810 may have a single-layer or multi-layer structure made of a metal material such as molybdenum (Mo), silver (Ag), titanium (Ti), copper (Cu), aluminum (Al), titanium/aluminum/titanium (Ti/Al/Ti), or molybdenum/aluminum/molybdenum (Mo/Al/Mo). However, the present disclosure is not limited thereto.

A touch insulating layer 820 may be disposed on the first touch electrode 810. The touch insulating layer 820 may be disposed across an entirety of the display area AA and non-display area NA and may extend to and be disposed on the pad area. The touch insulating layer 820 may be the second insulating layer. However, the present disclosure is not limited to the terminology.

The touch insulating layer 820 may be made of at least one inorganic material selected from silicon nitride (SiNx), silicon oxide (SiOx), and aluminum oxide (AlyOz). However, the present disclosure is not limited thereto.

A second touch electrode 830 may be disposed on the touch insulating layer 820. The second touch electrode 830 may be a plurality of sub-sensing electrodes or a plurality of sub-driving electrodes for the touch operation.

A touch line 840 for transmitting a touch driving signal may be disposed in the non-display area NA and may be formed in the same process as a process in which the second touch electrode 830 is formed.

The touch line 840 may overlap the first gate driving transistor GT1 or the second gate driving transistor GT2, and may extend to and be disposed on the pad area.

Each of the second touch electrode 830 and the touch line 840 may have a single-layer or multi-layer structure made of a metal material such as molybdenum (Mo), silver (Ag), titanium (Ti), copper (Cu), aluminum (Al), titanium/aluminum/titanium (Ti/Al/Ti), or molybdenum/aluminum/molybdenum (Mo/Al/Mo). However, the present disclosure is not limited thereto.

A third planarization layer 850 may be disposed on the second touch electrode 830 and the touch line 840.

The third planarization layer 850 may cover and planarize the second touch electrode 830, the touch line 840, and the touch insulating layer 820. Moreover, the third planarization layer 850 may be made of one or more organic insulating materials such as BCB (BenzoCycloButene), acryl resin, epoxy resin, phenolic resin, polyamide resin, or polyimide resin. However, the present disclosure is not limited thereto.

An adhesive layer 60 and a cover member 73 may be disposed on the third planarization layer 850. The cover member 73 may be referred to as ‘cover window’ or ‘cover glass’.

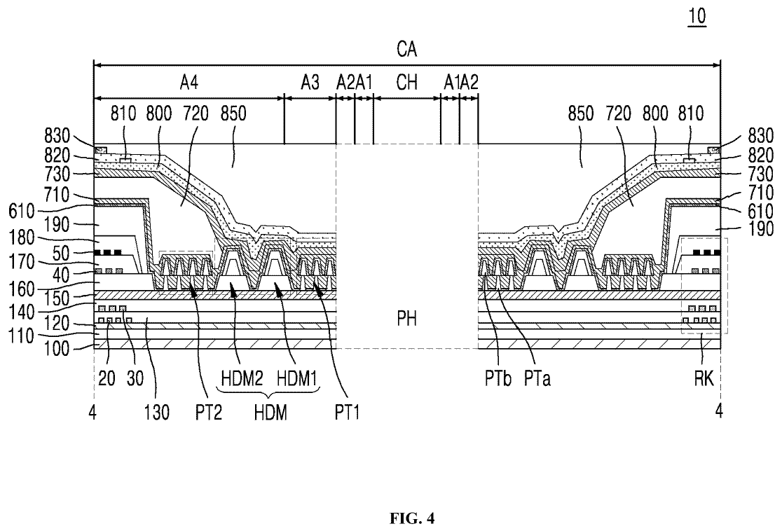

FIG. 4 is a cross-sectional view of a panel as cut along a cutting line 4-4′ of FIG. 1 according to an embodiment of the present disclosure.

Referring to FIG. 4, the camera area CA of the panel is described in detail.

The camera area CA includes a first hole area PH in which a camera is disposed in the display area AA, a first pattern area PT1 surrounding the first hole area PH, a first dam area HDM, a second pattern area PT2, and a routing line area RK.

The first hole area PH may be located in a center of the camera area CA, and may be formed to have a through-hole defined therein that physically extends through the substrate 100 to the third planarization layer 850. The first hole area PH may receive therein the camera, a sensor, and a light source. Light above the camera or the sensor may easily transmit through the first hole area PH.

In the routing line area RK, routing lines for electrically connecting the sub-pixels of the display area AA to each other in the camera area CA are disposed.

A first routing line 20 may be disposed on a portion of the first gate insulating layer 120 extending to the camera area CA and may be formed in the same process as the process of forming the first gate electrode 220, the second gate electrode 410, the first metal layer 300, the second metal layer 500, and the first capacitor electrode Cst1. Embodiments of the present disclosure are not limited thereto.

A second routing line 30 may be disposed on a portion of the second insulating layer 130 extending to the camera area CA and may be formed in the same process as the process of forming the second capacitor electrode Cst2. Embodiments of the present disclosure are not limited thereto.

A third routing line 40 may be disposed on a portion of the fourth insulating layer 160 extending to the camera area CA and may be formed in the same process as the process of forming the first source electrode 230S, the first drain electrode 230D, the second source electrode 420S, the second drain electrode 420D, the third source electrode 330S, the third drain electrode 330D, the fourth source electrode 530S, and the fourth drain electrode 530D. Embodiments of the present disclosure are not limited thereto.

A fourth routing line 50 may be disposed on a portion of the first planarization layer 170 extending to the camera area CA and may be formed in the same process as the process of forming the connection electrode 240. Embodiments of the present disclosure are not limited thereto.

In the routing line area RK, the first touch electrode 810 and the second touch electrode 830 may act as the routing line to electrically apply the touch driving signal to the display area AA.

Gate lines of the pixel circuit of the display area AA may be connected to the first routing line 20 and the second routing line 30 and thus may not be electrically disconnected in camera area CA. Data lines of the pixel circuit may be connected to the third routing line 40 and the fourth routing line 50 and may not be electrically disconnected in the camera area CA.

The first pattern area PT1 and the second pattern area PT2 are arranged to surround the first hole area PH. Each of the first pattern area PT1 and the second pattern area PT2 may include a plurality of patterns PT. Each of the plurality of patterns PT may include a lower pattern PTa and an upper pattern PTb. The lower pattern PTa may be made of the same material as that of the fourth insulating layer 160 while the lower pattern PTa and the fourth insulating layer 160 may be formed at the same time. The upper pattern PTb may be made of the same material as that of the second planarization layer 180, while the upper pattern PTb and the second planarization layer 180 may be formed at the same time. However, the material of the insulating layer and the number of layers of the plurality of patterns PT are not limited thereto.

Moreover, the plurality of patterns PT may be arranged to be spaced apart from each other by a certain distance.

The plurality of patterns PT may break the light-emitting element layer 610 extending from the display area AA to prevent moisture from penetrating into the display area AA through the light-emitting element layer 610 which is vulnerable to moisture penetration.

A width of a lower surface of the upper pattern PTb disposed on the lower pattern PTa is larger than a width of an upper surface of the lower pattern PTa.

The light-emitting element layer 610 disposed on the upper and side surfaces of the upper pattern PTb may not be formed on the side surface of the lower pattern PTa due to a separation space between the lower surface of the upper pattern PTb and the side surface of the lower pattern PTa. Thus, the light-emitting element layer 610 may be broken due to the plurality of patterns PT.

Moreover, the first encapsulating layer 710 may be disposed on the routing line area RK, the first pattern area PT1, the first dam area HDM, and the second pattern area PT2 of the camera area CA.

The first hole dam HDM1 and the second hole dam HDM2 may be disposed in the first dam area HDM between the first pattern area PT1 and the second pattern area PT2.

The first hole dam HDM1 and the second hole dam HDM2 may prevent or at least reduce the second encapsulating layer 720 from overflowing into the first hole area PH. A plurality of first hole dams HDM1 and a plurality of second hole dams HDM2 may be continuously arranged and may be disposed in the first pattern area PT1 and the second pattern area PT2.

Each of the first hole dam HDM1 and the second hole dam HDM2 may be formed by stacking the patterns made of the same material as and formed in the same process as those of the fourth insulating layer 160, the second planarization layer 180, and the bank 190. Embodiments of the present disclosure are not limited thereto.

Due to the first hole dam HDM1 and the second hole dam HDM2, the second encapsulating layer 720 may be disposed only on a portion of each of the second pattern area PT2 and the first dam area HDM.

The third encapsulating layer 730 may be disposed on the routing line area RK, the first pattern area PT1, the first dam area HDM, and the second pattern area PT2 of the camera area CA, and may contact a portion of the first encapsulating layer 710 disposed on the upper and side surfaces of the plurality of patterns PT of the first pattern area PT1.

The touch buffer layer 800, the touch insulating layer 820, and the third planarization layer 850 may be disposed on the routing line area RK, the first pattern area PT1, the first dam area HDM, and the second pattern area PT2 of the camera area CA and may extend to and may be disposed on the third encapsulating layer 730. The first hole area PH may overlap a second hole area CH, and the first area A1 and the second area A2 of the camera area CA. The first hole area PH may be a panel hole area. The second hole area CH may be the camera hole area CH.

A third area A3 of the camera area CA may overlap with the first pattern area PT1. A fourth area A4 of the camera area CA may overlap the first dam area HDM, the second pattern area PT2, and the routing line area RK.

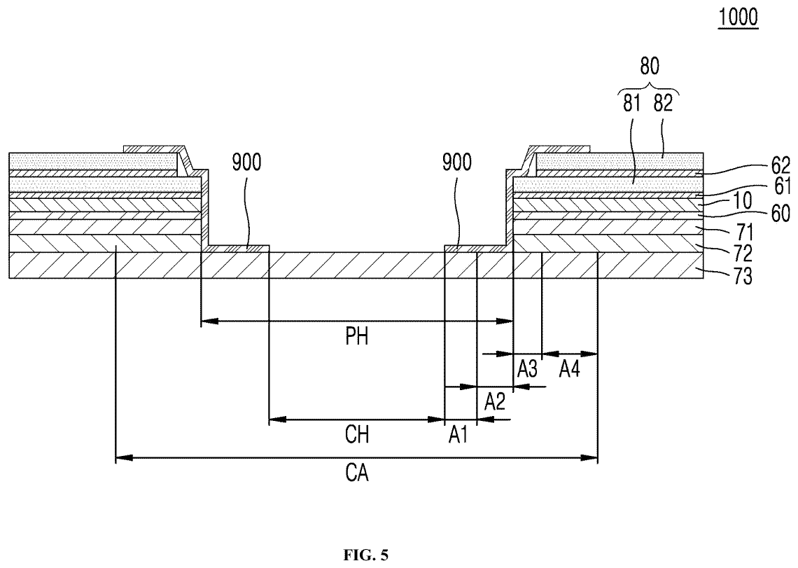

FIG. 5 is a cross-sectional view of a state in which a display device as cut along a cutting line 4-4′ of FIG. 2 is turned upside down according to an embodiment of the present disclosure.

Referring to FIG. 5, in the display device 1000 according to the present disclosure, the cover member 73 may be disposed under the panel 10, while a plate 80 including a support member 81 and a metal plate 82 may be disposed on the panel 10. The present disclosure is not limited to FIG. 5. Conversely, the plate 80 may be disposed under the panel 10, and the cover member 73 may be disposed on the panel 10.

The camera area CA including the first hole area PH may be formed in the panel 10.

The panel 10 and the plate 80 may have a through-hole defined therein in the camera area CA. A light-shielding tape 900 may be disposed on and along and attached to an inner side surface of the through-hole of the panel 10 and the plate 80, and a portion of a bottom surface thereof except for the second hole area CH of the cover member 73.

The light-shielding tape 900 may include a conductive material. The conductive material may include carbon black or silver (Ag). The light-shielding tape 900 may include a black material to prevent light-leakage.

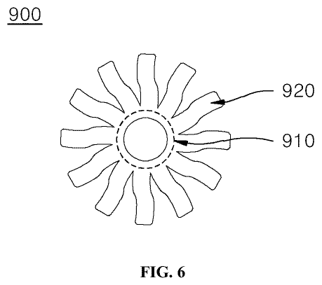

FIG. 6 is a diagram schematically showing a structure of a light-shielding tape according to an embodiment of the present disclosure.

As shown in FIG. 6, the light-shielding tape 900 may include a body 910 having a central through-hole defined therein, and legs 920 extending outwardly from the body 910. The multiple legs 920 may be formed to facilitate attachment during pressing.

The light-shielding tape 900 may include an adhesive layer, a conductive layer, and an insulating layer. The insulating layer may be omitted. The adhesive layer may be conductive and may physically connect the conductive layer to the cover member 73 facing the bottom surface of the through-hole.

The conductive layer and the adhesive layer of the light-shielding tape 900 may be made of conductive fibers and adhesive, respectively. A base material of the conductive layer may include conductive fibers, and aluminum (Al), copper (Cu), or nickel (Ni) foil. The adhesive layer may be disposed on one surface of the conductive layer.

The conductive layer may be formed using an electroless plating scheme and may be made of Ni, Cu, Cu+Ni, Cu+Ni+Gold, Cu+Ni+other metal, Cu+Ni+Resin, etc.

In FIG. 5, an optical control layer 71 may be attached to a bottom surface of the panel 10 by a first adhesive layer 60. The optical control layer 71 may include a polarizer. A cover adhesive layer 72 may be disposed between the optical control layer 71 and the cover member 73 such that the optical control layer 71 and the panel 10 may be attached onto the cover member 73 by the cover adhesive layer 72.

The optical control layer 71, the first adhesive layer 60, and the cover adhesive layer 72 may have a through-hole defined therein in the camera area CA. In this regard, the through-hole of the optical control layer 71, the first adhesive layer 60 and the cover adhesive layer 72 may have the same diameter as that of the through-hole of the panel 10 and the support member 81.

The cover adhesive layer 72 may made of an acrylic-based transparent adhesive material. The cover adhesive layer 72 may contract and expands depending on a temperature. Thus, the cover adhesive layer 72 may be deformed due to the temperature. In order to prevent the deformed cover adhesive layer 72 from expanding into the first hole area PH of the panel 10, the through-hole of the cover adhesive layer 72 may be larger than the through-hole of the optical control layer 71 and the first adhesive layer 60.

The camera area CA may further include the second hole area CH overlapping with the camera. The second hole area CH may be an area where the camera is located.

The camera area CA may include the first area A1, the second area A2, the third area A3, and the fourth area A4. The first area A1 is an area surrounding the second hole area CH and extending from an end of the second hole area CH to the second area A2. The second area A2 is an area extending from an end of the first area A1 to the inner side surface of the through-hole of the panel 10. The third area A3 is an area extending from an end of the second area A2 to an inner side end of the metal plate 82. The fourth area A4 is an area extending from an end of the third area A3 to an outer end of the light-shielding tape 900.

The first hole area PH of the panel 10 may overlap with the second hole area CH, the first area A1 and the second area A2.

The camera area CA may include the first pattern area PT1 overlapping the third area A3, and the first dam area HDM, the second pattern area PT2, and the routing line area RK overlapping the fourth area A4.

The panel 10 and the support member 81 may be attached to each other using a second adhesive layer 61. The support member 81 and the metal plate 82 may be attached to each other using a third adhesive layer 62.

A through-hole of the metal plate 82 may be larger than a through-hole of the support member 81.

The panel 10, the optical control layer 71, and the support member 81 are attached to each other using the first adhesive layer 60 and the second adhesive layer 61. Then, the through-hole is first formed therein such that the through-holes of the panel 10, the optical control layer 71, and the support member 81 has the same size.

The cover member 73 may be attached to the optical control layer 71 using the cover adhesive layer 72. The metal plate 82 to which the third adhesive layer 62 has been attached may be attached onto the support member 81 by the third adhesive layer 62.

The metal plate 82 and the third adhesive layer 62 having the through-hole formed therein are attached onto the support member 81. Thus, the width of the through-hole of the support member 81 and the width of the through-hole of each of the metal plate 82 and the third adhesive layer 62 may be different from each other.

Moreover, the through-hole of each of the metal plate 82 and the third adhesive layer 62 may be formed to be larger than the through-hole of the support member 81.

In FIG. 5 and FIG. 6, each of the legs 920 of the light-shielding tape 900 may extend in a straight upward direction from the bottom surface of the cover member 73 along the inner side surface of the through-hole of the support member 81 and may be attached thereto. Each of the legs 920 of the light-shielding tape 900 may cover a portion of the upper surface of the support member 81, and may be bent upwardly from the upper surface of the support member 81 so as to extend to an upper surface of the metal plate 82, and may cover a portion of the upper surface of the metal plate 82.

The display device 1000 may further include the first adhesive layer 60 and the optical control layer 71 disposed under the panel 10; and the cover adhesive layer 72 disposed between the optical control layer 71 and the cover member 73.

The optical control layer 71, the first adhesive layer 60 and the cover adhesive layer 72 may have the through-hole defined therein in the camera area CA.

The light-shielding tape 900 may be attached to the inner side surface of the through-hole of a combination of the support member 81, the panel 10, the optical control layer 71, the first adhesive layer 60, and the cover adhesive layer 72.

The body 910 of the light-shielding tape 900 may be attached to the inner side surface of the through-hole of a combination of the support member 81, the panel 10, the optical control layer 71, the first adhesive layer 60, and the cover adhesive layer 72.

The plurality of legs 920 of the light-shielding tape 900 may be attached to a portion of the upper surface of the metal plate 82.

The through-hole of each of the support member 81, the second adhesive layer 61, the panel 10, the optical control layer 71, the first adhesive layer 60, and the cover adhesive layer 72 may have a diameter that is smaller than a diameter of the through-hole of each of the metal plate 82 and the third adhesive layer 62.

In the display area AA, the plurality of pixels are disposed, wherein each pixel may include sub-pixels, and each sub-pixel may include a pixel circuit.

The pixel circuit may include at least one transistor, and each sub-pixel may include the first electrode electrically connected to the at least one transistor, the light-emissive layer, and the second electrode.

Each sub-pixel may include an encapsulating layer and a touch electrode disposed on the second electrode.

The display device 1000 may further include a camera, a sensor, and a light source disposed in the camera area CA.

The display device 1000 may further include a driving circuit and a dam area disposed in the non-display area NA.

Moreover, the display area AA of the panel 10 may include an organic light-emitting element (OLED) layer.

The organic light-emitting element layer includes multiple OLED elements. The OLED element is controlled by a pixel circuit and a driving circuit implemented on a substrate and another external driving circuit connected to a connection interface on the substrate.

The OLED layer includes an organic light-emitting material layer that emits light of a specific color, such as red, green, and blue. In some embodiments, the organic light-emitting material layer may have a stack structure capable of emitting white light (essentially a combination of different colors of light).

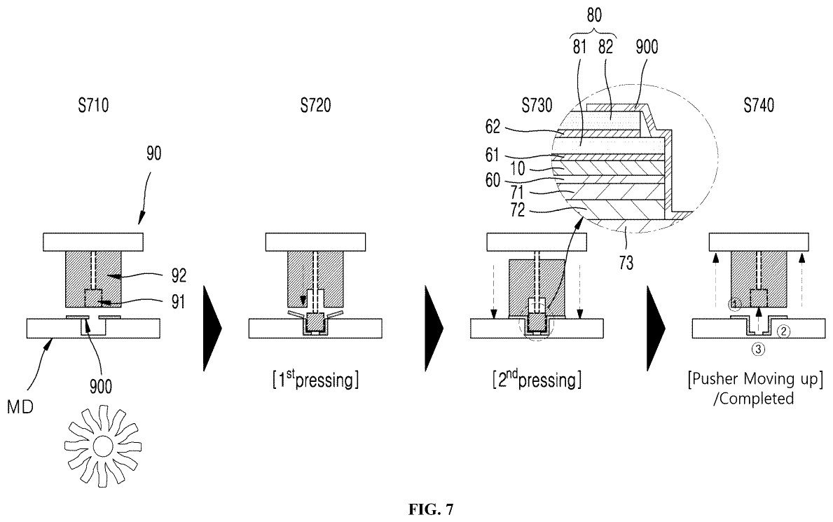

FIG. 7 is a flowchart illustrating a method for manufacturing a display device according to an embodiment of the present disclosure.

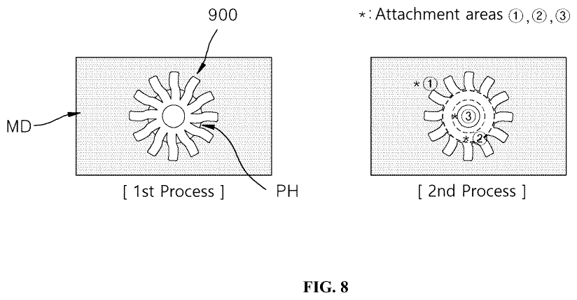

Referring to FIG. 7, in the manufacturing method of the display device 1000 according to the embodiment of the present disclosure, first, as in a first pressure-bonding process as shown in FIG. 8, the light-shielding tape 900 is placed on top of the through-hole PH of the module MD and the metal plate 82 in S710.

In this regard, the through-hole PH means the first hole area PH. In a top view of the light-shielding tape 900 as shown in FIG. 8, the body 910 is located in the center of the through-hole PH, and the legs 920 are arranged to be dispersed around the through-hole PH. FIG. 8 is a view showing an example in which the light-shielding tape according to the embodiment of the present disclosure is first and second pressure-bonded.

In FIG. 7, a pressure device 90 for a pressing operation may include a first pressure pusher 91 having a diameter smaller than the diameter of the through-hole PH and a second pressure pusher 92 having a diameter larger than the diameter of the through-hole PH.

Subsequently, the first pressure pusher 91 having the smaller diameter than that of the through-hole PH performs first pressing on the body 910 of the light-shielding tape 900 in S720.

At this time, the first pressure pusher 91 performs the first pressing until the body 910 of the light-shielding tape 900 is inserted into the through-hole PH and touches the bottom surface of the cover member 73.

Subsequently, the second pressure pusher 92 having a larger diameter than the diameter of the through-hole PH performs second pressing on the legs 920 of the light-shielding tape 900 in S730.

At this time, the second pressure pusher 92 presses the legs 920 of the light-shielding tape 900 overlapping the upper surface of the metal plate 82 until the legs touches the upper surface of the metal plate 82.

After the second pressure-bonding has been completed, the legs 920 of the light-shielding tape 900 may be attached to the upper surface of the metal plate 82 of the module MD in a dispersed manner, as shown in FIG. 8 (\textcircled{1}). A portion of the body 910 is attached to the side surface of the through-hole of each of the support member 81, the second adhesive layer 61, the panel 10, the first adhesive layer 60, the optical control layer 71, and the cover adhesive layer 72 defining the through-hole PH (\textcircled{2}). The other portion of the body 910 is attached to a portion of the upper surface of the cover member 73 corresponding to the bottom surface of the through-hole PH (\textcircled{3}).

Then, the first pressure pusher 91 and the second pressure pusher 92 are lifted up and are removed from the light-shielding tape 900 in S740.

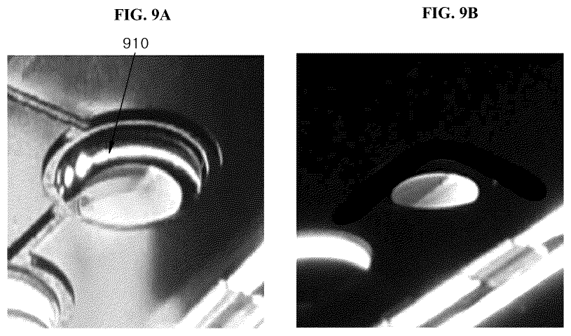

In the display device 1000 according to the embodiment of the present disclosure, after the light-shielding tape 900 has been attached to the through-hole PH of the camera area CA in the process as described above (TA), the light-leakage 910 is shielded as shown in FIG. 9. FIGS. 9A and 9B are images showing the light-leakage phenomenon before (e.g., FIG. 9A) and after (e.g., FIG. 9B) the light-shielding tape 900 is attached to the through-hole of the camera area of the display device according to the embodiment of the present disclosure. It may be identified that in the display device 1000 according to the embodiment of the present disclosure, the light-leakage phenomenon occurs before the light-shielding tape 900 is attached to the through-hole of the camera area CA, while after the light-shielding tape 900 is attached to the through-hole of the camera area CA, the light-leakage 910 is shielded.

Therefore, in the display device 1000 according to the embodiment of the present disclosure, the light-shielding tape may be attached to the through-hole of the camera area in the double pressing technique, thereby preventing the light-leakage and reducing the bright spot defect. The bright spot defect refers to a defect in which electric charges generated by friction against the cover member 73 are not discharged to the metal plate 82 but are transferred to the panel 10 such that the panel is damaged such that the light-leakage occurs around the camera hole.

As described above, according to the embodiment of the present disclosure, the display device may be realized in which the black ink as the conductive material is not disposed in the through-hole of the camera area, but the light-shielding tape for light-leakage shielding is inserted into the through-hole of the camera area, thereby preventing the light-leakage and reducing the bright spot defect.

Moreover, according to the embodiment of the present disclosure, the display device manufacturing method may be realized in which the light-shielding tape having the plurality of legs is disposed on top of the hole in the camera area in a display device, and then, the light-shielding tape is attached to the bottom of the hole in the first pressure-bonding, and then the multiple legs are attached to the periphery of the hole in the second pressure-bonding.

A display device according to an embodiment of the present disclosure may be described as follows.

A first aspect of the present disclosure provides a display device comprising: a panel including a display area and a non-display area, wherein a camera area including a first hole area is formed in the display area; a cover member disposed under the panel; and a plate disposed on top of the panel, wherein each of the panel and the plate has a through-hole defined therein in the camera area, wherein a light-shielding tape is disposed along and attached to an inner side surface of the through-hole of each of the panel and the plate.

In some implementations of the display device, the light-shielding tape includes a conductive material.

In some implementations of the display device, the light-shielding tape includes a black color material.

In some implementations of the display device, the light-shielding tape includes: a circular body having a through-hole defined in a center area thereof; and a plurality of legs extending outwardly from the body.

In some implementations of the display device, the camera area further includes a second hole area overlapping with a camera.

In some implementations of the display device, the camera area includes: a first area surrounding the second hole area and extending an outer end of the second hole area; a second area extending from an outer end of the first area to an inner side surface of the through-hole of the panel; a third area extending from an outer end of the second area to an inner side end of the metal plate; and a fourth area extending from an outer end of the third area to an outer end of the light-shielding tape.

In some implementations of the display device, the first hole area of the panel overlaps the second hole area, the first area, and the second area.

In some implementations of the display device, the camera area includes: a first pattern area overlapping the third area; and a first dam area, a second pattern area, and a routing line area overlapping the fourth area.

In some implementations of the display device, a width of the through-hole of the support member and a width of the through-hole of the metal plate are different from each other.

In some implementations of the display device, the through-hole of the metal plate is larger than the through-hole of the support member.

In some implementations of the display device, each of the legs of the light-shielding tape extends in a straight line in an upward direction from an edge of a bottom surface of the cover member along the inner side surface of the through-hole of the support member, and is attached to the inner side surface of the through-hole of the support member, wherein each of the legs of the light-shielding tape covers and is attached to a portion of an upper surface of the support member, and is bent from an end of the portion of the upper surface of the support member so as to cover and be attached to a portion of an upper surface of the metal plate.

In some implementations of the display device, the display device further comprises: a first adhesive layer and an optical control layer disposed under the panel; and a cover adhesive layer disposed between the optical control layer and the cover member.

In some implementations of the display device, each of the optical control layer, the first adhesive layer, and the cover adhesive layer has a through-hole defined therein in the camera area.

In some implementations of the display device, the light-shielding tape is attached to an inner side surface of the through-hole of each of the support member, the panel, the optical control layer, the first adhesive layer, and the cover adhesive layer.

In some implementations of the display device, the body of the light-shielding tape is attached to the inner side surface of the through-hole of each of the support member, the panel, the optical control layer, the first adhesive layer, and the cover adhesive layer.

In some implementations of the display device, a diameter of the through-hole of each of the support member, the panel, the optical control layer, the first adhesive layer, and the cover adhesive layer is smaller than a diameter of the through-hole of each of the metal plate and a third adhesive layer.

In some implementations of the display device, a plurality of pixels are disposed in the display area, wherein each of the pixels includes sub-pixels, wherein each of the sub-pixels includes a pixel circuit.

In some implementations of the display device, the pixel circuit includes at least one transistor, wherein each of the sub-pixels includes a first electrode electrically connected to the at least one transistor, a light-emissive layer, and a second electrode.

In some implementations of the display device, each of the sub-pixels includes an encapsulating layer and a touch electrode disposed on the second electrode.

In some implementations of the display device, the display device further comprises a camera, a sensor, and a light source disposed in the camera area.

In some implementations of the display device, the display device further comprises a driving circuit and a dam area disposed in the non-display area.

A second aspect of the present disclosure provides a method for manufacturing a display device, wherein the display device includes: a panel including a display area and a non-display area, wherein a camera area including a first hole area is formed in the display area; a cover member disposed on top of the panel; and a plate disposed under the panel and including a support member and a metal plate, wherein each of the panel and the plate has a through-hole defined therein in the camera area, wherein the method comprises: step a for positioning a light-shielding tape on top of the through-hole and the metal plate; step b, for first pressing a body of a light-shielding tape using a first pressure pusher having a smaller diameter than a diameter of the through-hole; step c for second pressing legs of the light-shielding tape using a second pressure pusher having a larger diameter than the diameter of the through-hole; and step d for removing the first and second pressure pushers from the light-shielding tape.

In some implementations of the method, in the step b, the first pressure pusher performs the first pressing until the body of the light-shielding tape touches a bottom surface of the cover member.

In some implementations of the method, in the step c, the second pressure pusher performs the second pressing on each of the legs of the light-shielding tape overlapping an upper surface of the metal plate until each leg touches the upper surface of the metal plate.

Although the embodiments of the present disclosure have been described in more detail with reference to the accompanying drawings, the present disclosure is not necessarily limited to these embodiments, and may be modified in a various manner within the scope of the technical spirit of the present disclosure. Accordingly, the embodiments as disclosed in the present disclosure are intended to describe rather than limit the technical idea of the present disclosure, and the scope of the technical idea of the present disclosure is not limited by these embodiments. Therefore, it should be understood that the embodiments described above are not restrictive but illustrative in all respects.

What is claimed is:

1. A display device comprising:
a panel including a display area and a non-display area, wherein a camera area including a first hole area is in the display area;
a cover member under the panel; and
a plate on the panel, the plate including a support member and a metal plate,
wherein each of the panel and the plate has a through-hole defined therein in the camera area,
wherein a light-shielding tape is disposed along and attached to an inner side surface of the through-hole of each of the panel and the plate.

2. The display device of claim 1, wherein the light-shielding tape includes a conductive material.

3. The display device of claim 1, wherein the light-shielding tape includes a black color material.

4. The display device of claim 1, wherein the light-shielding tape includes:
a circular body having a through-hole defined in a center area thereof; and
a plurality of legs extending outwardly from the circular body.

5. The display device of claim 1, wherein the camera area further includes a second hole area overlapping with a camera.

6. The display device of claim 5, wherein the camera area includes:
a first area surrounding the second hole area and extending to an outer end of the second hole area;
a second area extending from an outer end of the first area to an inner side surface of the through-hole of the panel;
a third area extending from an outer end of the second area to an inner side end of the metal plate; and
a fourth area extending from an outer end of the third area to an outer end of the light-shielding tape.

7. The display device of claim 6, wherein the first hole area of the panel overlaps the second hole area, the first area, and the second area.

8. The display device of claim 6, wherein the camera area includes:
a first pattern area overlapping the third area; and
a first dam area, a second pattern area, and a routing line area overlapping the fourth area.

9. The display device of claim 4, wherein a width of the through-hole of the support member is different from a width of the through-hole of the metal plate.

10. The display device of claim 9, wherein the width of the through-hole of the metal plate is larger than the width of the through-hole of the support member.

11. The display device of claim 10, wherein each of the plurality of legs of the light-shielding tape extends in a straight line in an upward direction from an edge of a bottom surface of the cover member along the inner side surface of the through-hole of the support member, and is attached to the inner side surface of the through-hole of the support member,
wherein each of the plurality of legs of the light-shielding tape covers and is attached to a portion of an upper surface of the support member, and is bent from an end of the portion of the upper surface of the support member so as to cover and be attached to a portion of an upper surface of the metal plate.

12. The display device of claim 9, wherein the display device further comprises:
a first adhesive layer and an optical control layer under the panel; and
a cover adhesive layer between the optical control layer and the cover member.

13. The display device of claim 12, wherein each of the optical control layer, the first adhesive layer, and the cover adhesive layer has a through-hole defined therein in the camera area.

14. The display device of claim 13, wherein the light-shielding tape is attached to an inner side surface of the through-hole of each of the support member, the panel, the optical control layer, the first adhesive layer, and the cover adhesive layer.

15. The display device of claim 14, wherein the circular body of the light-shielding tape is attached to the inner side surface of the through-hole of each of the support member, the panel, the optical control layer, the first adhesive layer, and the cover adhesive layer.

16. The display device of claim 14, wherein a diameter of the through-hole of each of the support member, the panel, the optical control layer, the first adhesive layer, and the cover adhesive layer is smaller than a diameter of the through-hole of each of the metal plate and a third adhesive layer.

17. The display device of claim 1, wherein a plurality of pixels are in the display area and each of the plurality of pixels includes sub-pixels, wherein each of the sub-pixels includes a pixel circuit.

18. The display device of claim 17, wherein the pixel circuit of each of the plurality of sub-pixels includes at least one transistor,
wherein each of the plurality of sub-pixels includes a first electrode electrically connected to the at least one transistor, a light-emissive layer, and a second electrode.

19. The display device of claim 18, wherein each of the plurality of sub-pixels includes an encapsulating layer and a touch electrode on the second electrode.

20. The display device of claim 1, wherein the display device further comprises a camera, a sensor, and a light source disposed in the camera area.

21. The display device of claim 1, wherein the display device further comprises a driving circuit and a dam area disposed in the non-display area.
